(19) United States
(12) Patent Application Publication
(10) Pub. No.: US 2004/0248375 A1
(43) Pub. Date: Dec. 9, 2004

(54) Trench filling methods

(76) Inventors: John McNeil, Cardiff (GB); Carl David Brancher, Monmouthshire (GB)

Correspondence Address: VOLENTINE FRANCOS, P.L.L.C., Suite 150, 12200 Sunrise Valley Drive, Reston, VA, 20191, US

(21) Appl. No.: 10/859,550

(22) Filed: Jun. 3, 2004

Related U.S. Application Data
(60) Provisional application No. 60/476,225, filed on Jun. 6, 2003.

(30) Foreign Application Priority Data
Jun. 4, 2003 (GB) 0312796.6

(51) Int. Cl. H01L 21/76

(52) U.S. Cl. 438/435; 438/424

(57) ABSTRACT

The invention consists in methods or processes for filling high aspect ratio recesses, such as shallow trench isolation structure wherein a flowable layer is deposited in the recess to reduce the aspect ratio of the recess and none of the flowable material is in the plane of the mouth of the recess, and the recess is subsequently filled by other material.

### CROSS-REFERENCE TO RELATED APLICATIONS

A claim to priority is made to U.S. Provisional Patent Application 60/476,225, filed 6^{th} Jun. 2003 and to British Patent Application No. 0312796.6, filed 4^{th} Jun. 2003, the contents of both of which are incorporated by reference.

### BACKGROUND OF THE INVENTION

1. Field of the Invention

This invention relates to methods of filling high aspect ratio trenches such as in forming trench isolation regions in semiconductor substrates.

2. Description of the Related Art

For economic and device speed reasons there is a continuing requirement to pack the active components of integrated circuits formed in the semiconductor wafer ever closer together. However for these components to function correctly they need to be isolated from each other. Accordingly electrical isolation between circuit elements is required and a known technique desirable for sub-micron devices is ‘shallow trench isolation’ (STI). The conventional methodology is to etch trenches into the substrate and then fill. As the packing density increases these trenches become narrower making it ever more difficult to fill these trenches by the conventional means. The most widely used means is ‘high density plasma chemical vapour deposition’ (HDP CVD) of silicon dioxide.

Like all vapour deposition techniques this has a problem whereby more material deposits on the upper surface and top edge of the trenches being the exact reverse of an ideal, which would be to fill the trenches exclusively.

To overcome this problem to some degree deposition cycles are interspersed or mixed with etch back by radio frequency driving of the wafer chuck to cause directional plasma etching of the deposited materials in a selective manner to remove more of the material at the surface thereby improving the net deposition on the trenches.

It has been reported that at <95 nm that HDP will have difficulties in filling structures with aspect ratio of >4.5:1, see “Novel Shallow Trench Isolation process using flowable oxide CVD for sub-100 nm DRAM”, Sung-Woong Chung et al, IEDM 2001.

A tapering of the sidewalls such that the width at the mouth of the trench is much wider than the base, may assist filling. This is undesirable, but is considered necessary to achieve filling by conventional HDP CVD means and such tapering will be seen in all diagrams and electron micrographs of viable structures.

As an alternative, it is known that flowable oxides e.g. those that deposit a silanol or similar offer a potential for trench filling either alone or in combination with plasma deposited insulators. These flowable oxides may be spun on or vapour deposited.

The ideal case would be to completely fill with the flowable oxide, which by its nature leaves little upon the upper surface of the wafer. There are however as yet unsolvable problems in converting the liquid to a dense solid suitable for semiconductor device manufacture. The narrow trench provides an extremely limited surface from which to evolve water, solvent and other vapours driven off as the material is hardened. Various attempts have been made to improve this process including the applicants own U.S. Pat. No. 6,544,858 but none have as yet provided a commercially acceptable solution to the problems outlined above.

This then leaves the concept of a partial fill, whereby the flowable oxide is used to partially fill, thereby reducing the aspect ratio of the trench. As the liquid deposited is thinner it is easier to fully harden and the reduction in aspect ratio assists the conventional HDP CVD process.

In particular U.S. Pat. No. 6,300,219 describes a process using a flowable oxide invented by the applicants and broadly as described in U.S. Pat. No. 5,874,367 and U.S. Pat. No. 6,242,366. In this disclosure the first layer deposited effectively lowers the aspect ratio (defined as trench depth to width) preferably by filling at least about one third of the depth of the trench whilst only adding at most 20 nanometers of layer to the sidewalls. As a result any subsequent layer deposited to fill the trench will have a trench with a lower aspect ratio more conducive to filling without voids.

Another ‘partial fill’ process to lower the aspect ratio of trenches is described in US2002/0123206 and the related paper “Void free and low stress shallow trench isolation technology using P—SOG for sub-100 nm device”, Jin-Hwa Heo et al, VLSI 2002, pp132-133”.

Whilst good results may be obtained in structures of similar size, real semiconductor substrates have a range of trench widths, with narrow trenches for device separation and much wider trenches elsewhere. In practice such trenches fill to varying levels and the nature of the deposit tends to vary with aspect ratio as mentioned below. Flowable oxides requiring curing and hard baking to remove (organic) solvents, water etc. will have varying degrees of resistance to chemical etch depending on the topography of the surface they have been deposited upon. Typically narrow trenches that restrict the evolution of vapour from the flowable oxide cause the cured and baked oxide material to be less ‘hard’ than the flowable oxide in wider trenches.

Etching back the cured film therefore encounters varying etch rates with more material remaining in wider trenches. This problem is eloquently presented in US2003/0030121 (same inventors as in US2002/0123206 above) in FIGS. 1,2 and 3.

FIGS. 1, 2 and 3 of US 2003/0030121 are reproduced here as FIGS. 1, 2 and 3. In FIG. 1 a silicon wafer 10 is shown containing STI recesses 41 and a broader recess 42. A pad oxide layer 20 and CMP etch stop layer 30, typically of silicon nitride have been formed and pattered by photo resist and used as a mask to etch the structures 41, 42. Note that the sidewalls of the structures are sloped. A spin on glass (SOG) 50 has been deposited such that it completely fills the STI recesses 41.

It should also be noted that the SOG material contains impurities that if diffused into the silicon will cause device problems. There is therefore a need for a conformal silicon nitride barrier layer within the trenches deposited by low pressure CVD means. This is a high temperature process and therefore a thermal oxidation of the silicon is first formed to protect the silicon surface.

At FIG. 2 it can be seen that after etch back, the SOG 52 in the wider recess is still upon the sidewalls of the recess 42 and lies above the surface plane of the wafer 10. This is because the SOG in the wider recess 42 etches more slowly than the SOG 51 in the narrow recesses 41. A HDP oxide 60 has been deposited and CMP processed and the CMP etch stop layer 30 removed leaving thermal oxide 20 remaining upon the surface of the wafer between the recesses. At FIG. 3 reveals what happens when the thermal oxide layer 20 is removed. This exposes SOG 53, which rapidly etches in the wet etchant for removing the thermal oxide layer 20, whilst SOG 51 in the narrow recesses is completely protected by HDP oxide 61. In practice this problem may even become evident during the CMP step.

US2003/0030121 proposes a solution whereby the STI features are protected by a photoresist mask during a first etch back process to remove a SOG material from the wider recesses. This resist mask is then removed and a second etch back is performed on the flowable oxide in the STI features to ensure that none of the flowable oxide remains upon the upper surface of the wafer or the sidewalls of the STI features and therefore will not be exposed by subsequent CMP or wet etch steps.

Whilst this approach should work, it is extremely complex requiring additional barrier layer deposition (because of the use of SOG), an additional photoresist patterning step and two etching steps.

There therefore remains the requirement to fill, in a cost effective manner, trenches of varying widths and aspect ratios where some are shallow trench isolation features and others are wider structures. Ideally the material subjected to the CMP step should be the already used HDP CVD oxide and therefore the ideal solution is one that enables this well established production process to be used for device manufacture where alone it cannot fill the narrower trenches required by next generation semiconductor devices.

Much prior art focuses upon the narrow STI recesses and completely ignores this problem and thereby does not present viable processes for commercial use.

### SUMMARY OF THE INVENTION

From one aspect the invention consists in a process of forming shallow trench isolation structures in a semiconductor wafer wherein there is a first flowable oxide layer deposited to reduced the aspect ratio (depth to width) and a subsequent layer is deposited to fill the trench wherein none of the flowable layer in the shallow trench isolation structures is at the plane of the upper surface of the semiconductor wafer.

From another aspect the invention consists in a method of filling high aspect ratio recesses in a semiconductor wafer having an upper surface lying in a plane comprising:

(a) flowing a flowable dielectric material into the recesses to fill partially the recesses;

(b) completing the filling of the recesses with another dielectric material characterised in that there is no flowable material in the plane of the semi-conductor upper surface when step (b) is performed.

From a still further aspect the invention consists in a method comprising forming a trench in the semiconductor substrate and depositing a flowable material such as silanol e.g. Si(OH)ₓ and hardening it by removing OH and any solvents to form a layer that partially fills at least one trench and ensuring that there is no flowable layer on the side walls of the recesses above the plane of the top surface of the wafer prior to depositing the subsequent layer that fills the trenches.

This absence of the flowable layer at the top edges of the trenches may be achieved by changing the wetting properties e.g. by a surface tension modification process, and/or modifying the aspect ratio of the structure prior to the deposition of the silanol like aspect of the first layer, and/or by a selective etch process prior to the deposition of the subsequent layer. It is preferred that a vapour deposition methodology is used for the flowable oxide thereby avoiding the use of (organic) solvents and thereby removing the previous requirement for additional barrier layers such as thermal oxide and conformal silicon nitride.

Although the invention has been defined above it is to be understood it includes any inventive combination of the features set out above or in the following description.

### BRIEF DESCRIPTION OF THE DRAWINGS

FIGS. 1, 2 and 3 are representations of the prior art contained within US2003/0030121 and at FIG. 3 present the problem to be solved.

FIGS. 4, 5 and 6 describe embodiments of the invention being a diagrammatic cross sectional view of a wafer with recesses of different aspect ratios to be filled.

### DETAILED DESCRIPTION OF THE PREFERRED EMBODIMENTS

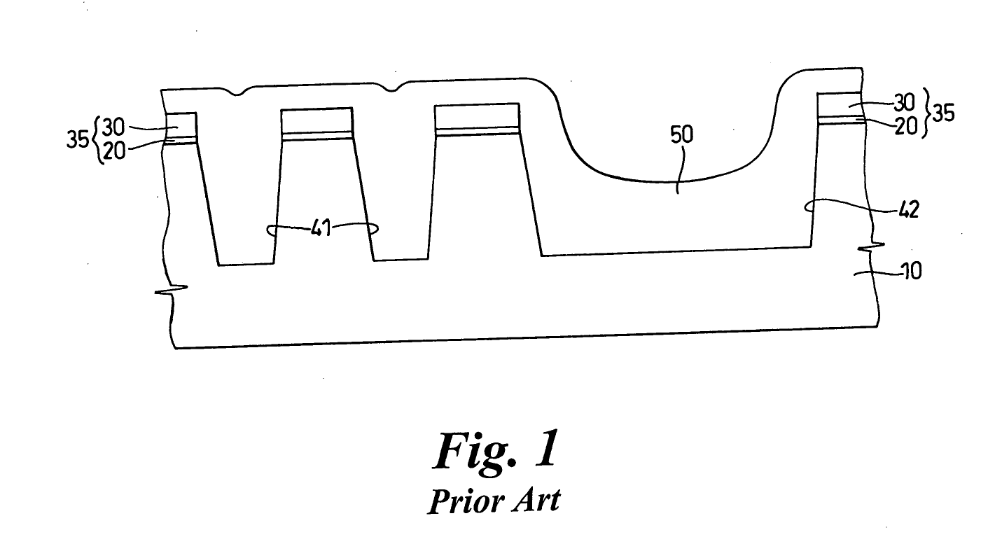

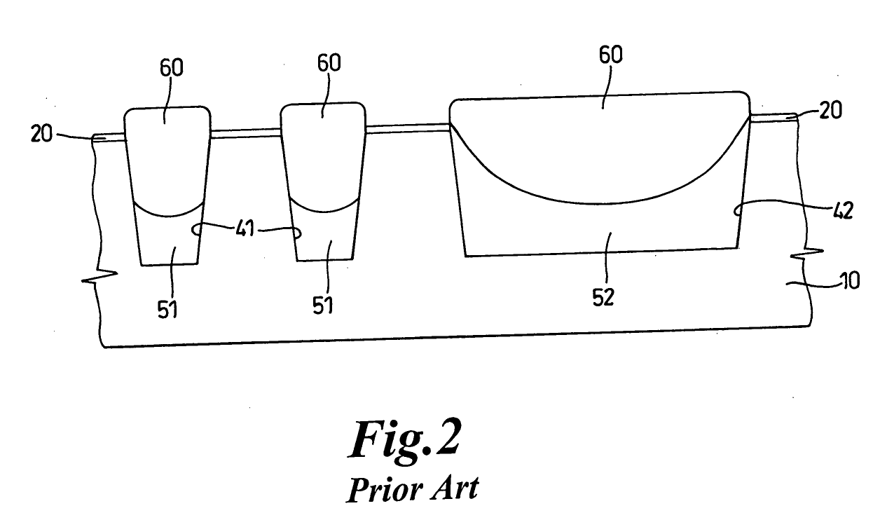

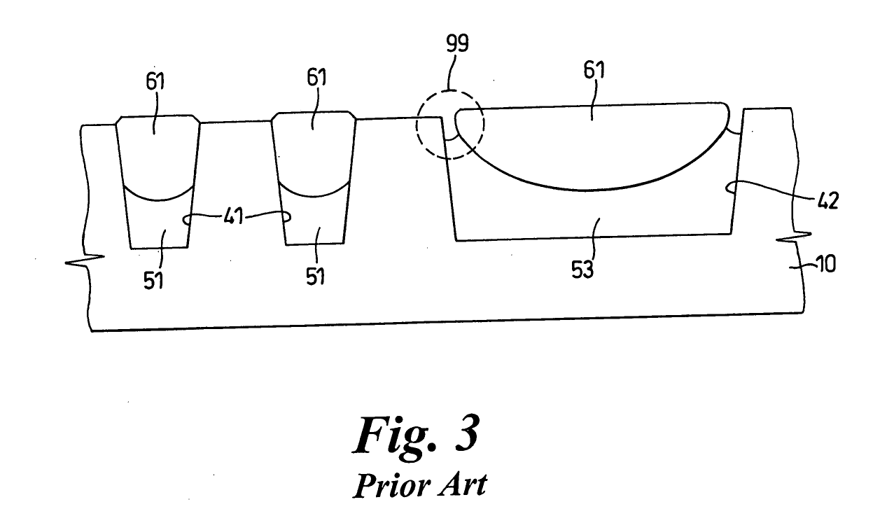

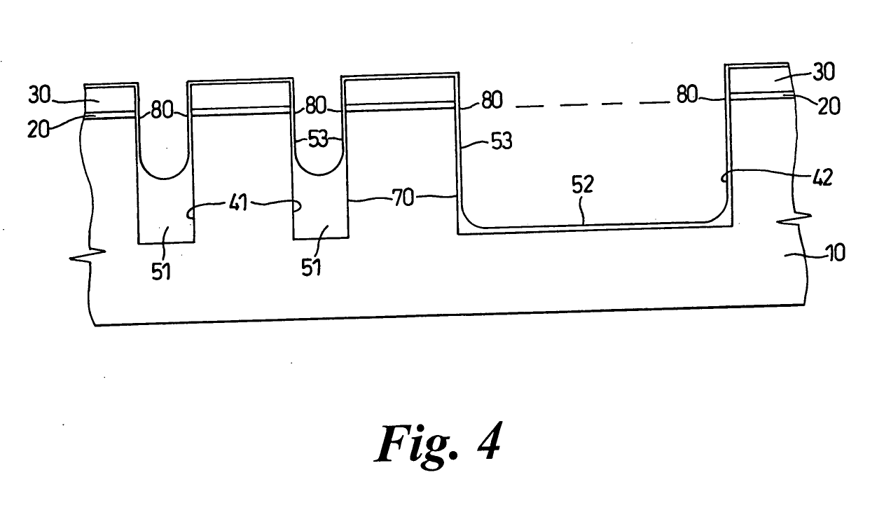

At FIG. 4 can be seen a structure broadly as in FIGS. 1 to 3 except that the recess walls 70 do not require tapering and can be near vertical and thereby the recess widths at their bases are the same as FIGS. 1 to 3. This allows closer spacing, saving space. It is also difficult to slope recess sidewalls repeatably and controllably, and where the material to be deposited is a flowable oxide, and in particular a vapour deposited flowable oxide then a slope is unnecessary. Suitable oxides include those of the applicants broadly as described in U.S. Pat. No. 5,874,367 and U.S. Pat. No. 6,242,366. These have the advantage over spin-on glasses as they have no solvent. Even inorganic spin-on glasses require an organic solvent and where the solvent cannot be entirely removed, such as in STI processing, then additional processes such as silicon nitride encapsulation is required, as described in US 2003/0030121.

It is a feature of this invention that none of the recesses are completely filled and further that this flowable oxide is either not deposited, or is removed from the sidewalls 70 above the level of the wafer 10 at 80 without a subsequent lithography step. As can be seen at FIG. 4, simply depositing a flowable oxide to fill partially recesses 41 will inevitably leave flowable oxide 50 not just in small and large recesses 41, 42 but also deposited on the sidewalls 70 of the recesses, as at 53, and upon the etch stop layer 30 due to the effects of surface tension.

Recesses 41, 42 are partially filled and due to the flowable nature of the material the sidewalls 70 need not be sloped to increase the width of the trenches at their mouths. In general larger recesses 42 received less material in their base 52. The amount of flowable oxide in a recess will be a function of the volume of material deposited, the volume of the recesses and the landed area of wafer around the recesses.

In some embodiments, the wafer is either treated to modify wetting properties such that flowable oxide 50 is discontinuous across the wafer and lies only within recesses and is not above the level of the upper surface of the wafer, or the layer 50 is treated after deposition to modify its surface tension and/or the layer 50 is rendered discontinuous by creating a lip to the upper edges of the recesses 41, 42 by increasing the aspect ratio of the recesses 41, 42 at their mouths by either an etch or deposition step such that the flowable oxide is rendered discontinuous between recesses 41, 42. Alternatively or additionally a selective dry etch may be used that removes flowable oxide 50 more rapidly at the upper surface of the wafer 10 and around the edges of the recesses 41, 42 than at the bases of the recesses. Such an etch process could utilize the saturation of etch species within the narrow recesses 41.

A suitable etch process might be a wet etch (typically 10:1 or 100:1 BOE) though a high pressure (100's of millitorr to over 1 torr) fluorine plasma etch is probably more appropriate as, whilst it is chemical in nature it will preferentially etch material outside the small recesses 41 due to saturation of the etch species within the narrow recesses. Alternatively a sputter etch or a high sputter component etch may be used, taking advantage of the preferred sputter etching on the sloped surfaces at the tops of the trenches. Sloped surfaces sputter etch faster than surfaces either normal or perpendicular to the flux.

A suitable reactive plasma etch process would preferably be a high pressure diode mode (opposing electrode RF driven) fluorinated etch and could most preferably be carried out in the deposition chamber. Most preferably the layer 50 on the wafer 10 could be etched back during at least part of the chamber clean process.

As all deposition chambers require periodic cleaning to remove deposition from chamber internal surfaces then to maximize productivity the wafer could remain, after deposition, in the process chamber for at least part of this cleaning cycle and have at least part of layer 50 removed.

Experimental results to date indicate a combination of increased aspect ratio and plasma etch back are sufficient to provide the necessary discontinuity.

The dewetting properties can be altered by localised coating, smoothing or densification of the side walls. For example a dewetting layer such as polytetrafluoroethylene (PTFE) may be deposited upon etch stop layer 30. After etching the recesses and removing the photoresist layer the PTFE layer will remain on the landed surface of the wafer, but not within the recesses thereby enabling or assisting, in combination with other aspects of the invention, the avoidance of flowable material at the plane of the wafer top surface during the completion of the recess filling. The change in the surface tension properties of the flowable material 50 could be achieved by for example a low power helium plasma post deposition of the flowable oxide prior to its setting. By this or other means the surface tension of the flowable oxide in the recess could be broken such that it no longer wets to the sidewalls of the recesses thereby forming a meniscus with upward curvature (as mercury does to glass).

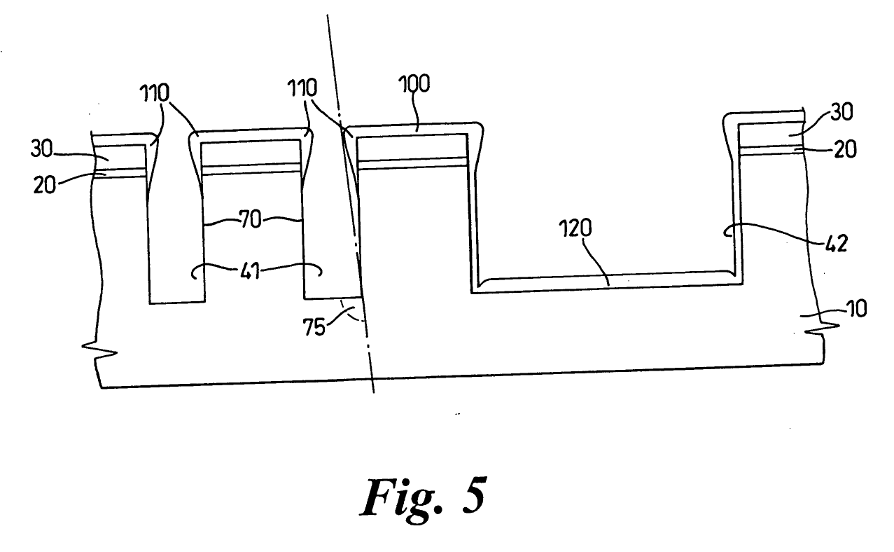

At FIG. 5 is shown an aspect of the invention where a layer 100 has been deposited in a manner to deliberately ‘neck’ the top of the small recesses 41 such that the aspect ratio at the top of these recesses is increased (depth to width). Such a layer would preferably be of a plasma chemical or sputter deposited oxide and will deposit upon the bases of wider recesses 42 at 120 to a similar thickness to the top of the wafer at 110. However the necking at 110 and the restriction in active species to the recesses 41 causes only extremely limited deposition within the recesses 41. This necking has little on no impact of the amount of flowable oxide deposited at the base of the small recesses 41, but acts as a ‘lip’ greatly reducing the amount of flowable oxide on the sidewalls 70 above the level of the wafer 10.

A re-entrant profile to the sidewalls 70 could also be achieved during the etching of the recesses to achieve the same ‘lip’ effect without or in addition to the deposition of layer 100. Certainly as sidewalls 70 no longer need to be positively sloped to assist in filling by conventional means then the sidewall angle 75 to vertical may be greater than 90 degrees.

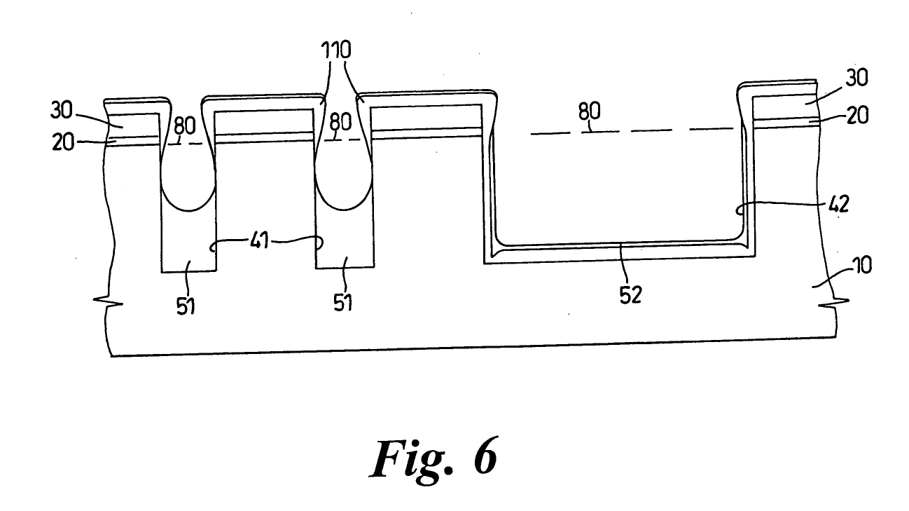

At FIG. 6 can be seen a flowable oxide 50 upon a structure as shown in FIG. 5. As can be seen flowable oxide 51 has entered recesses 41. Because of the profile of the layer 100 at 110 the flowable oxide is however discontinuous and is not present upon the sidewalls at 80 being the plane of the upper surface of the wafer. More particularly 80 represents the top of the structure after subsequent CMP and wet etching.

Depending on trench profile it may prove to be desirable to use the “necking” approach defined above with a short etch back process sequence. This is likely to be the case when the trench wall angle 75 has a significant taper e.g. >950 and there is a variety of small trenches and large trenches. The maximum thickness of the non-conformal oxide will ideally best suit the smallest recesses. These will have the greatest flowable oxide thickness and the flowable oxide thickness may prove to be insufficient to address isolated recesses that have less flowable oxide. In this case the etch back process not only removes flowable oxide but also opens the non-conformal deposition that “necked” the recesses, thus making the subsequent filling step less demanding.

What is claimed is:

1. A process of forming shallow trench isolation structures in a semiconductor wafer wherein there is a flowable layer deposited to reduce the aspect ratio (depth to width) of a trench and a subsequent layer is deposited to fill the trench wherein none of the flowable layer in the shallow trench isolation structures is at the plane of the upper surface of the semiconductor wafer.

2. A process of forming shallow trench isolation structures in a semiconductor wafer wherein there is a flowable layer deposited to reduce the aspect ratio (depth to width) of a trench and a subsequent layer is deposited to fill the trench wherein subsequent chemical mechanical polishing and wet chemical etching does not contact any part of the flowable layer.

3. A process as claimed in either claim 1 or claim 2 wherein the flowable layer is removed from the trench sidewalls at the plane of the top surface of the semiconductor wafer prior to deposition the subsequent layer.

4. A process as claimed in either claim 1 or claim 2 wherein the trench sidewall angle at the trench mouth is greater than 90 degrees to the trench base such that the flowable material is discontinuous between substantially all the trenches on a semiconductor wafer and upon the upper surface of the wafer.

5. A process as claimed in claim 4 wherein the sidewall angle is modified by the deposition of a layer prior to the deposition of flowable oxide.

6. A process as claimed in claim 1 or claim 2 wherein the flowable materials is an oxide.

7. A process as claimed in claim 1 or claim 2 wherein the flowable material is a silanol.

8. A process as claimed in claim 1 or claim 2 where there is no silicon nitride layer in the recess.

9. A method of filling high aspect ratio recesses in a semiconductor wafer having an upper surface lying in a plane comprising:
(a) flowing a flowable dielectric material into the recesses to fill partially the recesses;
(b) completing the filling of the recesses with another dielectric material characterised in that there is no flowable material in the plane of the semiconductor upper surface when step (b) is performed.

10. A method as claimed in claim 9, wherein the partial filling is controlled to prevent deposition of the flowable dielectric material at the plane.

11. A method as claimed in claim 9 wherein the surface adjacent the recesses is coated or otherwise treated so that it dewets the flowable dielectric material.

12. A method as claimed in claim 11 wherein the adjacent surface is coated with a non-wetting material.

13. A method as claimed in claim 11 wherein the flowable dielectric is treated prior to setting to cause it not to wet to the recess sidewalls.

14. A method as claimed in claim 9 wherein flowable material in the plane of the semiconductor surface is removed prior to step (b).

15. A method as claimed in claim 9 wherein the mouths of the recesses are formed to create a deposition discontinuity for the flowable material.

16. A method as claimed in claim 15 wherein the mouths of the recesses have overhanging lips.

17. A method as claimed in claim 15 wherein the overhanging lips are formed by a deposited layer.

18. A method as claimed in claim 16 wherein the deposited layer is removed prior to step (b).

19. A method as claimed in claim 13 wherein the lips of the mouths are re-entrant.

20. A method as claimed in claim 9 wherein there are recesses of different depths and/or aspect ratios.
